(19) United States
(12) Patent Application Publication
(10) Pub. No.: US 2020/0044138 A1
(43) Pub. Date: Feb. 6, 2020

(54) DEVICE BASED ON ALKALI METAL NIOBATE COMPRISING A BARRIER LAYER AND MANUFACTURING PROCESS

(71) Applicant: COMMISSARIAT A L'ENERGIE ATOMIQUE ET AUX ENERGIES ALTERNATIVES, Paris (FR)

(72) Inventors: Aomar HALIMAOUI, LA TERRASSE (FR); Cécile MOULIN, GRENOBLE (FR); Guillaume RODRIGUEZ, GRENOBLE (FR)

(21) Appl. No.: 16/528,231

(22) Filed: Jul. 31, 2019

(30) Foreign Application Priority Data
Aug. 2, 2018 (FR) 1857235

(51) Int. Cl. H01L 41/08; H01L 41/187; H01L 41/319; H01L 41/316

(52) U.S. Cl. CPC H01L 41/0815; H01L 41/316; H01L 41/319; H01L 41/1873

(57) ABSTRACT

A piezoelectric device includes at least one upper layer of piezoelectric material based on alkali metal niobate and one lower layer of metal located above a substrate, wherein it comprises a barrier layer of material that is a barrier to the diffusion of alkali metals into the metal and that is inert to the alkali metals of the niobite, the barrier material layer being located between the lower layer of metal and the upper layer of piezoelectric material. A process for producing the device is also provided.

### CROSS-REFERENCE TO RELATED APPLICATIONS

This application claims priority to foreign French patent application No. FR 1857235, filed on Aug. 2, 2018, the disclosure of which is incorporated by reference in its entirety.

### FIELD OF THE INVENTION

The field of the invention is that of piezoelectric materials that crop up in many applications. The most important applications are notably: RF filters, actuators, (MEMS) transducers.

### BACKGROUND

The piezoelectric materials used industrially are typically:
PbZrTiO₃ (PZT) for actuators (and transducers); however, regarding the future of PZT, the European WEEE (Waste Electrical and Electronic Equipment) Regulations require the elimination of Pb in the not so distant future. Identical regulations have been adopted by the USA, Canada, Japan, China and Korea. It is thus becoming necessary to replace this material with lead-free materials;
AlN for RF filters and transducers. It is however sought to replace AlN with a more efficient material that has a better coupling coefficient. A few coupling coefficients are mentioned below in comparison with AlN: Kₜ²=7% (AlN), Kₜ²=12% (AlNSc), Kₜ²>40% (LiNbO₃).

Regarding AlNSc (with Sc between 10% and 40%): this material from the AlN family should not pose any deposition problems; however, difficulties are encountered in manufacturing targets using the element Sc. Furthermore, Sc is an element which is not very abundant and is therefore expensive.

Other promising materials are currently being studied such as: KₓNa₁₋ₓNbO₃ (KNN) for actuator applications and LiNbO₃ (LNO) for RF filter applications.

Regarding KₓNa₁₋ₓNbO₃(KNN): this material is difficult to deposit. Currently, a single Japanese company (SIOCS), specialized in provision of substrates, proposes well crystallized KNN layers deposited on Pt (100 mm wafers).

Regarding LiNbO₃ (LNO): developments have already been achieved with bulk LNO substrates (100 mm in diameter) used as donor substrate for transferring, to an acceptor substrate, crystalline thin layers of LNO (Smart Cut™ process). However, this material is difficult to deposit according to currently published processes.

Regarding the processes for depositing piezoelectric material, the most well known are in particular:
laser ablation deposition processes: “Pulsed Laser Deposition” (PLD), offering very encouraging results, despite equipment that is not yet fully developed;
sputtering processes, for which the equipment is already fully developed and widely used in industry. Tests have been carried out for depositing LNO, KNN and PZT, but still encounter difficulties.

Regarding the aforementioned devices (filters, actuator, transducer generally), all use Metal-Insulator-Metal (MIM) structures.

FIG. 1 illustrates an example of a device comprising such a structure. More specifically, on a substrate 10 is produced: a Bragg mirror structure (reflector in the case of RF filters) 11, a bottom electrode 12, a layer of piezoelectric material 13 and a top electrode 14, making it possible to produce a piezoelectric transducer.

With regard to the metal/piezoelectric material compatibility, it is in particular known to use:
Pt with perovskites (PZT, KNN);
Mo with AlN, AlNSc (wurtzite);
Pt or Mo with LNO.

These metals are the most used, even though other metals are possible, in particular Ti in the case of AlN.

For the filters, it is also possible to use depositions on insulator and to only use surface electrodes, in order for example to produce a surface acoustic wave device, commonly known as SAW, these devices however being used less and less for the production of RF filters because they are limited in terms of power and frequency. FIGS. 2a and 2b illustrate this type of surface acoustic wave device. On a substrate 20, a layer of insulator 21, a layer of piezoelectric material 22 and interdigital electrodes 23 are produced. FIG. 2b illustrates a top view of the surface electrodes 23.

A report of certain studies carried out by the company SIOCS is summarized below regarding the performance of a piezoelectric device using the deposition of KNN by sputtering on Pt metal and more particularly a device such as the one illustrated in FIG. 3 which shows a 525 μm thick Si wafer, a 2 nm Ti attachment layer, a 200 nm Pt conductive layer on which a deposition of 3 μm of KNN was produced.

The table below is taken from the reference:

https://www.sciocs.com/english/products/KNN.html

| | |
|---|---|
| for actuator | for sensor |

| | |
|---|---|
| materials | KNN = (K,Na)NbO₃ |
| thickness | 1~5 μm (typical 2~3 μm) |
| wafer diameter | 4 inch, 6 inch |
| substrate | Si, SOI |

| | | |
|---|---|---|
| piezoelectric constant | d₃₁ = 100 pm/V | d₃₁ = 80 pm/V |
| dielectric constant | 900 | 350 |

The authors obtained very satisfactory results in terms of a well-oriented crystalline phase, as FIG. 4 demonstrates, with good-quality crystallographic peaks. However, the authors do not describe the processes for obtaining the KNN layer and FIG. 3 does not show any intermediate layer at the Pt/KNN interface.

The deficiency in alkali metal elements of a layer made of KNN material is furthermore known in the literature. Notably, the publication: “Alkali ratio control for lead-free piezoelectric films utilizing elemental diffusivities in RF plasma” by Hussein Nili, Ahmad Esmaielzadeh Kandjani, Johan Du Plessis, Vipul Bansal, Kourosh Kalantar-zadeh, Sharath Sriram and Madhu Bhaaskaran, provides less satisfactory results. FIG. 5 taken from this publication demonstrates several orientations for KNN and 3 phases, whereas it is desired to obtain one orientation and one phase.

Within this context, the applicant has sought to understand the phenomena involved during the formation of the layer of piezoelectric material.

In order to obtain a satisfactory quality of the layer of piezoelectric material in contact with the metal layer on which it must be deposited, it is necessary that the metal layer, for example made of Pt or Mo, be of good quality itself. In this regard, the production of a well-oriented Pt (111) layer, that can thus be used for depositing piezoelectric material, is controlled.

The quality and also the orientation of the layer of piezoelectric material throughout its thickness is dependent on the deposition of the first layers deposited by sputtering.

It is therefore necessary to control the composition of the first layers but the prior art described in certain publications demonstrates depositions that are substoichiometric (lack of Na and K especially at the interface) and that relate to depositions of KNN by RF plasma.

The schematic representation of FIG. 6 shows the elements present: Li, LiOₓ, NbOₓ, at the surface of the Pt layer after sputtering, with a view to the formation of a layer of LiₓNbO_{y}. It would therefore be advisable to control the stoichiometry of the layer and to adjust the conditions for deposition (flow of O₂, Ar, pressure, etc.) and the composition of the target, in order to obtain stoichiometric LiNbO₃.

Reality is more complex and various species are formed as illustrated by the schematic representation of FIG. 7.

As soon as the first layers are deposited, the Li diffuses and reacts with the Pt, thus creating an Li deficiency in the first layers deposited. This Li deficiency leads to the formation of other phases. Furthermore, the reaction of Pt with Li leads to the formation of a Pt—Li compound which changes the configuration of the surface on which the remainder of the deposition is carried out. The reactivity of Li with Pt is entirely likely. Indeed, the authors J. Sangster and A. D. Pelton from the Ecole Polytechnique de Montrëal, in “The Li-Pt (Lithium-Platinum) System”, Journal of Phase Equilibria Vol. 12 No. 6 1991, described the formation of PtLiₓ eutectics starting from 290° C.

The same behaviour was described with the other alkali metals (Na, K) and the noble metals: “Reactions between Some Alkali and Platinum Group Metals” by O. Loebich, Jr. and Ch.J. Raub, Forschungsinstitut für Edelmetalle and Metallchemie, Schwäbisch Gmünd, Germany, in Platinum Metals Rev., 25, (3), 113-120. The diffusion of the alkali metals into the metals was also described as very rapid starting from 100° C., in “Diffusion of Alkali Metals in Molybdenum and Niobium”, M. G. Karpman, G. V. Scherbedinskii, G. N. Dubinin, and G. P. Benediktova.

To prevent the diffusion and the reaction of alkali metals (Li, Na, K) with the bottom electrode, the applicant proposes to incorporate a barrier layer at the surface of the bottom electrode. In order to be effective, this barrier must be inert (non-reactive) with respect to the alkali metals and the metal of the bottom electrode (Pt, Mo, etc.). This barrier must also be capable of preventing the diffusion of the alkali metals towards the bottom electrode.

### SUMMARY OF THE INVENTION

More specifically, one subject of the present invention is a piezoelectric device comprising at least one upper layer of piezoelectric material based on alkali metal niobate and one lower layer of metal located above a substrate, characterized in that it comprises a barrier layer of material that is a barrier to the diffusion of alkali metals into said metal and which layer is inert to the alkali metals of said niobate and that said barrier material layer being located between the lower layer of metal and the upper layer of piezoelectric material.

The piezoelectric material may notably be KNN or LNO.

According to variants of the invention, the metal is Pt or any other metal such as Mo or Ti.

According to variants of the invention, said diffusion barrier material is a conductive oxide or a conductive nitride, it being possible for the oxide to comprise a Pt or Ru or Ir metal and preferably RuO₂.

According to variants of the invention, said diffusion barrier material is a nitride that may be TiN or WN or TaN and preferably TiN.

According to variants of the invention, the barrier material is an insulating or semiconductor material that may be a piezoelectric material.

According to variants of the invention, the thickness of the barrier layer is greater than several tens of nanometres and preferably of the order of around a hundred nanometres.

According to variants of the invention, the device comprises, between the surface of the substrate and said lower layer of metal, when this metal is a noble metal, a layer for attachment of said noble metal, it being possible for the attachment layer to be made of TiO₂.

According to variants of the invention, the thickness of the lower layer of metal, which may be a noble metal, being greater than several tens of nanometres, the thickness of the attachment layer is of the order of a few nanometres.

According to variants of the invention, the device comprises a conductive upper layer above the layer of piezoelectric material.

Another subject of the invention is a process for manufacturing a device according to the invention, comprising the following steps:
depositing a lower layer of metal, which may be a noble metal, on a substrate;
producing a barrier layer on the surface of said lower layer of metal;
depositing a layer of a piezoelectric material on the surface of said barrier layer by sputtering from a target.

According to variants of the invention, the sputtering is carried out at a temperature above 300° C., preferably above 500° C.

According to variants of the invention, the process comprises at least one sputtering step carried out at a pressure of a few mTorr in order to deposit the piezoelectric material.

According to variants of the invention, the process comprises a first sputtering step carried out at a first RF power, and a second sputtering step carried out with a second RF power higher than the first power, in order to deposit the piezoelectric material.

According to variants of the invention, the first RF power is of the order of 200 W, the second RF power being of the order of 500 W.

According to variants of the invention, the process comprises the deposition of an attachment layer on the surface of the substrate, prior to the deposition of the lower layer of metal.

According to variants of the invention, the process comprises carrying out a deposition of upper layer of metal.

### BRIEF DESCRIPTION OF THE DRAWINGS

The invention will be better understood and other advantages will become apparent on reading the following description, which is given in a non-limiting manner, and by virtue of the figures wherein:

FIG. 1 depicts a transducer-type device according to the known art;

FIGS. 2a and 2b depict a surface acoustic wave device according to the known art;

FIG. 3 illustrates a photograph of a stack of KNN on the surface of a Pt layer according to the known art;

FIG. 4 illustrates the crystallographic peaks of a layer of KNN on a layer of Pt (111) according to the known art;

FIG. 5 illustrates the crystallographic peaks of a layer of KNN deposited on a Pt metal showing various crystalline orientations of KNN and various phases, according to the known art;

FIG. 6 depicts the formation of a layer of LiₓNbO_{y} from the sputtering of a target;

FIG. 7 depicts the diffusion of alkali metals into the layer of metal and the formation of various phases other than LiₓNbO_{y};

FIG. 8 illustrates a first example of a device according to the invention comprising a barrier layer according to the invention;

FIG. 9 illustrates a second example of a device according to the invention;

FIG. 10 illustrates an example of an MIM device according to the invention.

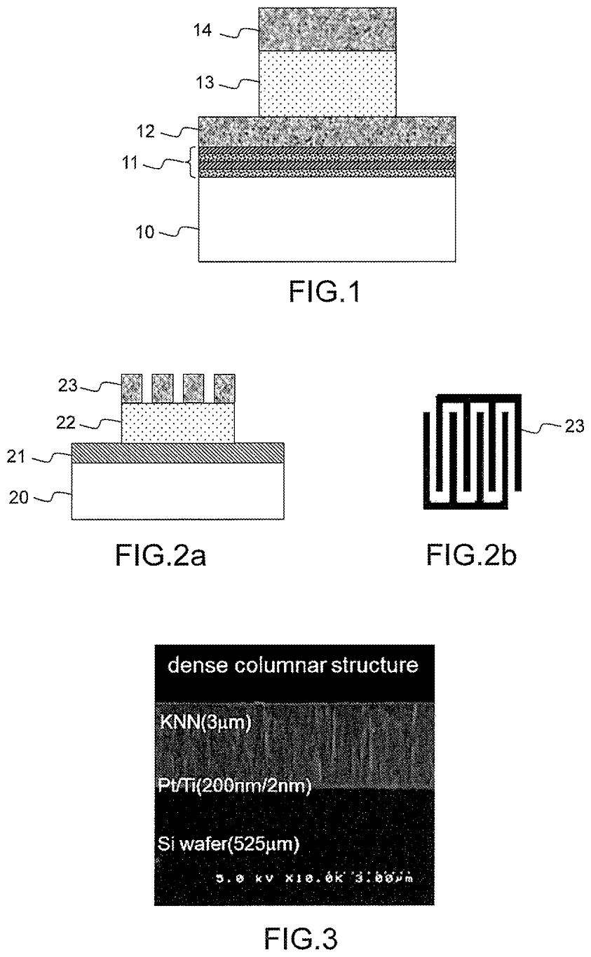

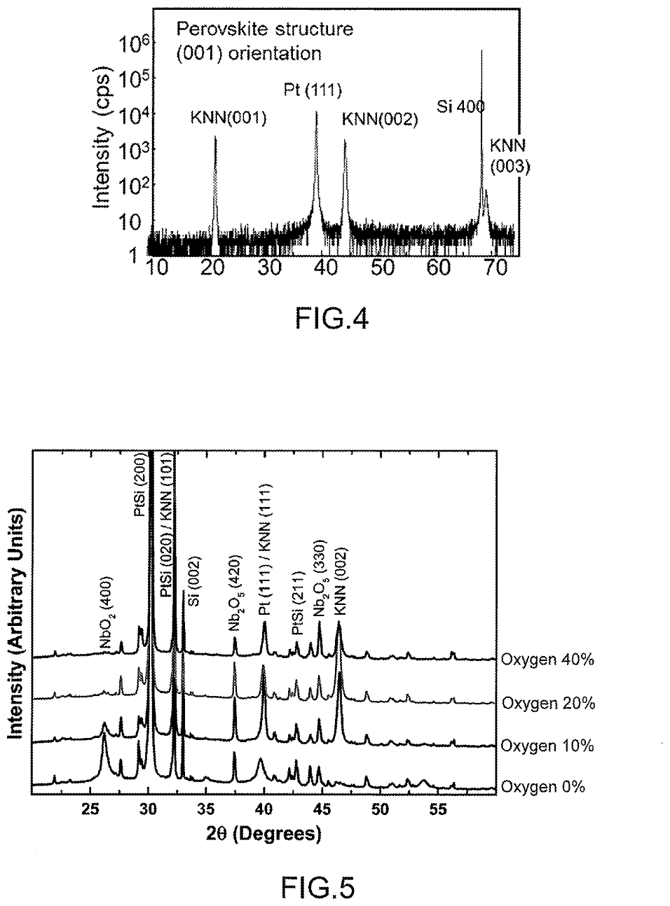

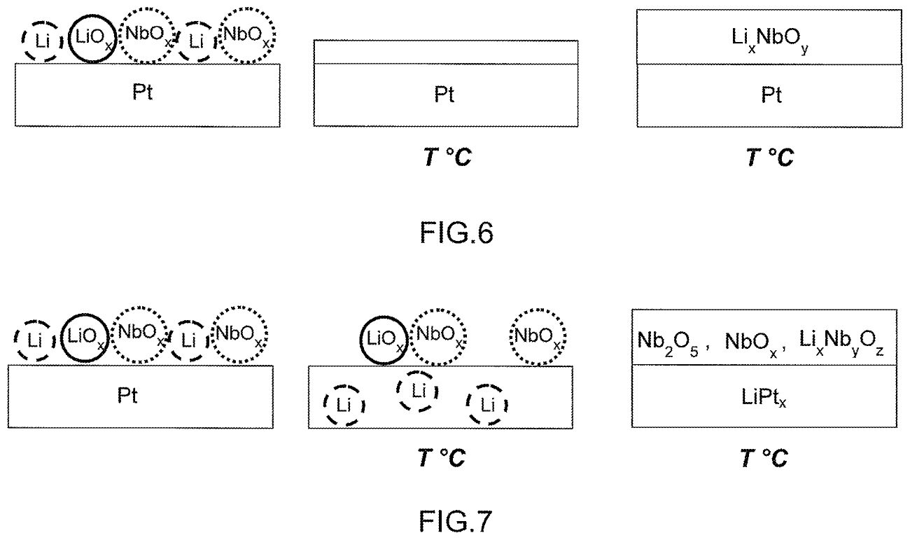

### DETAILED DESCRIPTION

Generally, the device of the invention comprises, on the surface of a substrate, a conductive layer of metal, on which it is sought to deposit a good-quality layer of alkali metal piezoelectric material, through the intermediary of a barrier layer.

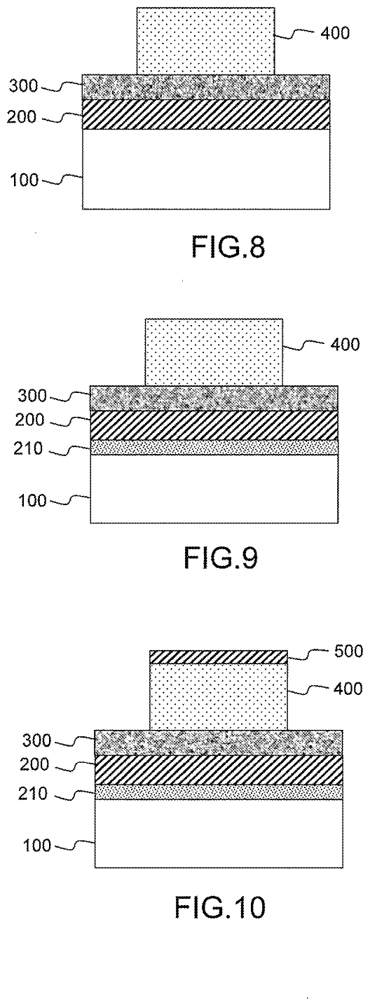

FIG. 8 depicts a first example of a device of the invention, showing a substrate 100, a layer of noble metal 200, a barrier layer 300, a layer of piezoelectric material 400.

The stack, described in detail below, is deposited on a substrate suitable for the intended application and which may be a sapphire, MgO, glass or else silicon substrate or preferably an Si substrate covered with an insulating layer (preferably a layer of SiO₂).

Before the deposition of the piezoelectric material, the metallic bottom electrode (i.e. the layer 200) is first deposited, followed by the deposition of the barrier layer 300. To form the bottom electrode of one of the aforementioned devices, use may preferably be made of Pt or Mo.

For the barrier material of the barrier layer, it is possible to use any material having the role of:
preventing alkali metals (Li, Na, K) from reacting with the bottom electrode; and
preventing these same alkali metals from diffusing towards the bottom electrode.

Since these barrier materials must be chemically inert with respect to the alkali metals, use is preferably made of oxides or nitrides.

In field of conductive nitrides and oxides, use may be made of oxides of noble metals (Pt, Ru, Ir) and preferably of RuO₂.

In field of nitrides, it is possible to use TiN, WN, TaN and preferably TiN.

The use of an insulating barrier is also possible. However, so as not to degrade the response of the piezoelectric material, it is preferable to use a barrier which is also piezoelectric, such as aluminium nitride (AlN), for example.

It may be advantageous to provide an attachment layer that promotes the attachment of the metal layer to the substrate.

FIG. 9 illustrates, for this purpose, a second example of a device of the invention comprising, on a substrate 100:

an attachment layer 210;

a metal layer 200;

a barrier layer of barrier material 300;

a layer of piezoelectric material 400.

FIG. 10 illustrates the same stack as the one described previously and represented in FIG. 9, supplemented by an upper electrode that makes it possible to produce an MIM-type device, i.e. the following stack:

a substrate 100;

an attachment layer 210;

a metal layer 200;

a barrier layer of barrier material 300;

a layer of piezoelectric material 400;

a top electrode 500.

To produce the aforementioned device illustrated in FIG. 9, the steps of a standard process are the following:

Step 1:

To improve the adhesion of this Pt layer on the substrate, an attachment layer made of TiO₂, for example, a few nm thick (5 nm) is deposited beforehand.

Step 2:

The deposition of a Pt electrode having a thickness of a few tens of nm, for example 100 nm, on the surface of said attachment layer is carried out.

Step 3:

On the Pt layer, the deposition of the barrier layer of barrier material, which may be RuO₂, is carried out. In order to be effective against the diffusion of the alkali metals, the thickness of this barrier layer must be at least 80 nm (preferably 100 nm) for a deposition temperature of the piezoelectric material of between 500° C. and 700° C.

Step 4:

The piezoelectric material (LiNbO₃ or KₓNa₁₋ₓNbO₃) is deposited by sputtering using a target corresponding to the material to be deposited. The deposition is carried out at a temperature above 300° C., preferably at 500° C. For the sputtering, use is made of an Ar:O₂ mixture at a pressure of a few mTorr and preferably 5 mTorr. The Ar:O₂ ratio may be adjusted in order to obtain the desired deposition velocity while limiting the amount of oxygen vacancies in the piezoelectric material. This Ar:O₂ ratio is preferably around 4:1.

For the sputtering machine used notably within the context of a 200 mm Si wafer, the RF power is a few hundred watts, typically 500 W.

Another variant consists in depositing the piezoelectric material by sputtering using two RF powers. It is advantageous to begin the deposition of the first layers at a lower RF power (200 W, for example), then to increase the RF power to 500 W after 15 minutes.

1. A piezoelectric device comprising at least one upper layer of piezoelectric material based on alkali metal niobate and one lower layer of metal located above a substrate, wherein it comprises a barrier layer of material that is a barrier to the diffusion of alkali metals into said metal and that is inert to the alkali metals of said niobate, said barrier material layer being located between the lower layer of metal and the upper layer of piezoelectric material, said diffusion barrier material being a conductive oxide or a conductive nitride.

2. The device according to claim 1, wherein the metal is Pt or Mo or Ti.

3. The device according to claim 1, wherein the oxide comprises a Pt or Ru or Ir metal and preferably RuO₂.

4. The device according to claim 1, wherein said diffusion barrier material is a nitride that may be TiN or WN or TaN and preferably TiN.

5. The device according to claim 1, wherein the thickness of the barrier layer is greater than several tens of nanometres and preferably of the order of around a hundred nanometres.

6. The device according to claim 1, comprising, between the surface of the substrate and said lower layer of metal, when this metal is a noble metal, a layer for attachment of said noble metal, for example made of TiO₂.

7. The device according to claim 6, wherein the thickness of the lower layer of metal, which may be a noble metal, being greater than several tens of nanometres, the thickness of the attachment layer is of the order of a few nanometres.

8. The device according to claim 1, comprising a conductive upper layer above the layer of piezoelectric material.

9. A process for manufacturing a device according to claim 1, comprising the following steps:
depositing a lower layer of metal, which may be a noble metal, on a substrate;
producing a barrier layer on the surface of said lower layer of metal;
depositing a layer of a piezoelectric material on the surface of said barrier layer by sputtering from a target.

10. The manufacturing process according to claim 9, wherein the sputtering is carried out at a temperature above 300° C., preferably at 500° C.

11. The manufacturing process according to claim 9, comprising at least one sputtering step carried out at a pressure of a few mTorr in order to deposit the piezoelectric material.

12. The manufacturing process according to claim 11, comprising a first sputtering step carried out at a first RF power, and a second sputtering step carried out with a second RF power higher than the first power, in order to deposit the piezoelectric material.

13. The manufacturing process according to claim 9, comprising the deposition of an attachment layer on the surface of the substrate, prior to the deposition of the lower layer of metal.

14. The manufacturing process according to claim 9, comprising carrying out a deposition of upper layer of metal.
